(19) United States
(12) Patent Application Publication
(10) Pub. No.: US 2013/0147022 A1
(43) Pub. Date: Jun. 13, 2013

(54) SEMICONDUCTOR DEVICES AND METHODS OF FABRICATING THE SAME

(71) Applicant: Samsung Electronics Co., Ltd., Suwon-Si (KR)

(72) Inventors: Jung-soo YOON, Hwaseong-si (KR); Jongwon HONG, Hwaseong-si (KR); Insun PARK, Seoul (KR); Jongmyeong LEE, Seongnam-si (KR); Seung-Wook CHOI, Daegu (KR)

(73) Assignee: SAMSUNG ELECTRONICS CO., LTD., Suwon-Si (KR)

(21) Appl. No.: 13/706,960

(22) Filed: Dec. 6, 2012

(30) Foreign Application Priority Data
Dec. 7, 2011 (KR) 10-2011-0129966

(51) Int. Cl. H01L 29/06

(52) U.S. Cl. CPC H01L 29/0607
USPC 257/637

(57) ABSTRACT

A semiconductor device may include an interlayer insulating layer containing hydrogen and a first passivation layer configured to prevent or inhibit an out-gassing of the hydrogen. In the method, a second passivation layer configured to control a warpage characteristic of a wafer may be formed on the first passivation layer.

### CROSS-REFERENCE TO RELATED APPLICATIONS

This U.S. non-provisional patent application claims priority under 35 U.S.C. §119 to Korean Patent Application No. 10-2011-0129966, filed on Dec. 7, 2011, the entirety of which is incorporated by reference herein.

### BACKGROUND

1. Field

Example embodiments of the inventive concepts relate to semiconductor devices and/or methods of fabricating the same.

2. Description of the Related Art

Semiconductor manufacturing methods may include an etching process, and the etching process may cause surface damage to a semiconductor substrate. As semiconductor devices become more and more integrated, a space between patterns may become reduced and the surface damage of the semiconductor substrate may be increased. Thus, dangling bonds of silicon constituting the semiconductor substrate may be increased. The dangling bonds may function as a source of a leakage current, thereby generating the leakage current in a transistor.

### SUMMARY

Example embodiments of the inventive concepts may provide a semiconductor device with improved leakage current characteristic. Example embodiments of the inventive concepts may also provide a method of fabricating a semiconductor device capable of improving a leakage current characteristic and controlling a warpage characteristic of a wafer.

According to example embodiments, a semiconductor device may include interconnections on a substrate, an interlayer insulating layer covering the interconnections, a first passivation layer on the interlayer insulating layer, and a second passivation layer on the first passivation layer, the second passivation layer having a density lower than a density of the first passivation layer.

In example embodiments, the first passivation layer may be formed of a silicon nitride layer having the density of about 2.6 g/cm³ or more, and the second passivation layer may be formed of a silicon nitride layer having the density less than about 2.6 g/cm³.

In example embodiments, the first passivation layer may have a compressive stress characteristic, and the second passivation layer may have a tensile stress characteristic.

In example embodiments, the first passivation layer may have a thickness of about 2000 Å or more.

In example embodiments, the semiconductor device may be a DRAM device.

In example embodiments, the semiconductor device may further include a third passivation layer on the second passivation layer. The third passivation layer may be formed of polyimide.

In example embodiments, the interlayer insulating layer may have a tensile stress characteristic.

In example embodiments, the interlayer insulating layer may include hydrogen. The hydrogen may be combined with a dangling bond of a surface of the substrate through the interconnection.

According to example embodiments, a method of fabricating a semiconductor device may include forming interconnections on a substrate, forming an interlayer insulating layer covering the interconnections, the interlayer insulating layer including hydrogen, forming a first passivation layer configured to inhibit an out-gassing of the hydrogen on the interlayer insulating layer, and forming a second passivation layer configured to control a warpage characteristic on the first passivation layer.

In example embodiments, the first passivation layer may be formed under a process condition having at least one of a gas flow rate lower than, a pressure lower than, and a power higher than when forming the second passivation layer.

In example embodiments, the method may further include performing a thermal treatment process to cure a defect of a surface of the substrate with the hydrogen.

In example embodiments, the interlayer insulating layer may be formed by a chemical vapor deposition method using oxygen and silane. A flow rate of the silane may have a range of about 50% to about 70% of a flow rate of the oxygen.

According to example embodiments, a semiconductor device may include interconnections on a substrate, at least one interlayer insulating layer on the interconnections, and at least two passivation layers on the at least one interlayer insulating layer. One of the at least two passivation layers may have a compressive stress characteristic, and the other of the at least two passivation layers may have a tensile stress characteristic.

In example embodiments, the at least two passivation layers may include first and second passivation layers, and the first passivation layer may have a thickness of about 2,000 Å or more.

In example embodiments, the at least two passivation layers may include first, second and third passivation layers, and the third passivation layer may be formed of polyimide.

In example embodiments, a density of each of the second and third passivation layers may be less than a density of the first passivation layer.

In example embodiments, the at least one interlayer insulating layer has a tensile stress characteristic.

In example embodiments, the at least one interlayer insulating layer may include hydrogen, and the hydrogen may be combined with a dangling bond of a surface of the substrate through the interconnections.

### BRIEF DESCRIPTION OF THE DRAWINGS

Example embodiments of the inventive concepts will become more apparent in view of the attached drawings and accompanying detailed description.

FIGS. 1 to 4 are cross-sectional views illustrating a method of fabricating a semiconductor device according to example embodiments of the inventive concepts;

FIG. 5 is a graph illustrating an effect of the method according to example embodiments of the inventive concepts;

FIG. 6 is a schematic diagram illustrating an example of electronic systems including semiconductor devices according to example embodiments of the inventive concepts; and

FIG. 7 is a schematic diagram illustrating an example of memory cards including semiconductor devices according to example embodiments of the inventive concepts.

### DETAILED DESCRIPTION OF EXAMPLE EMBODIMENTS

The inventive concepts will now be described more fully hereinafter with reference to the accompanying drawings, in which example embodiments of the inventive concepts are shown. The advantages and features of the inventive concepts and methods of achieving them will be apparent from the following example embodiments that will be described in more detail with reference to the accompanying drawings. It should be noted, however, that the inventive concepts are not limited to the following example embodiments, and may be implemented in various forms. Accordingly, example embodiments are provided only to disclose the inventive concepts and let those skilled in the art know the category of the inventive concepts. In the drawings, example embodiments of the inventive concepts are not limited to the specific examples provided herein and are exaggerated for clarity.

The terminology used herein is for the purpose of describing particular embodiments only and is not intended to limit the inventive concepts. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, example embodiments in the detailed description will be described with sectional views as examples of the inventive concepts. Accordingly, shapes of the example views may be modified according to manufacturing techniques and/or allowable errors. Therefore, example embodiments of the inventive concepts are not limited to the specific shape illustrated in the example views, but may include other shapes that may be created according to manufacturing processes. Areas illustrated in the drawings have general properties, and are used to illustrate specific shapes of elements. Thus, this should not be construed as limited to the scope of the inventive concepts.

It will be also understood that although the terms first, second, third etc. may be used herein to describe various elements, these elements should not be limited by these terms. These terms are only used to distinguish one element from another element. Thus, a first element in some example embodiments could be termed a second element in other example embodiments without departing from the teachings of the inventive concepts. Example embodiments of the inventive concepts explained and illustrated herein include their complementary counterparts. The same reference numerals or the same reference designators denote the same elements throughout the specification.

Moreover, example embodiments are described herein with reference to cross-sectional illustrations and/or plane illustrations that are idealized example illustrations. Accordingly, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments. Hereinafter, example embodiments of the inventive concepts will be described with reference to the drawings.

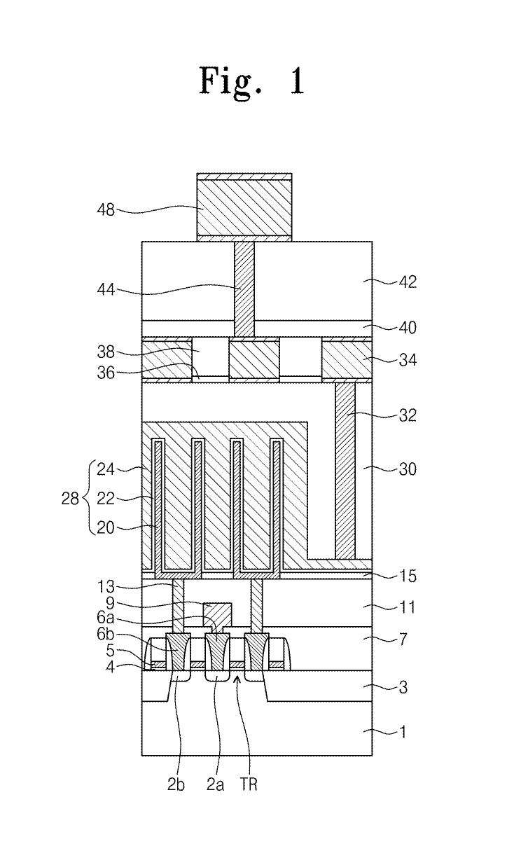

FIGS. 1 to 4 are cross-sectional views illustrating a method of fabricating a semiconductor device according to example embodiments of the inventive concepts. Referring to FIG. 1, a device isolation layer 3 may be formed on a substrate 1 to define an active region. For example, the substrate 1 may be a silicon single-crystalline substrate, a silicon epitaxial layer substrate, or a SOI (silicon on insulator) substrate. For example, the device isolation layer 3 may be formed by a shallow trench isolation (STI) method. Gate electrodes 5 may be formed on the substrate 1 with a gate insulating layer 4 therebetween. A first dopant injection region 2a and a second dopant injection region 2b may be formed in the substrate 1 at both sides of the gate electrodes 5, respectively.

The gate electrode 5 and the dopant injection regions 2a and 2b may constitute a transistor TR. Both sidewalls of the gate electrode 5 may be covered by spacers and a top surface of the gate electrode 5 may be covered by a capping pattern. A first contact 6a and a second contact 6b may be formed between the gate electrodes 5. The first and second contacts 6a and 6b may be formed in a self-align method. A first interlayer insulating layer 7 may be formed to cover the first and second contacts 6a and 6b and the transistors TR. A first interconnection 9 may be formed on the first interlayer insulating layer 7. For example, the first interconnection 9 may correspond to a bit line. The first contact 6a connected to the first interconnection 9 may be a bit line node contact. The first dopant injection region 2a connected to the first contact 6a may correspond to a common drain region.

Subsequently, a second interlayer insulating layer 11 may be formed to cover the first interconnection 9. A third contact 13 connected to the second contact 6b may be formed to penetrating the second interlayer insulating layer 11. A first etch stop layer 15 may be formed on the second interlayer insulating layer 11. A capacitor 28 consisting of a lower electrode 20, a dielectric layer 22, and an upper electrode 24 may be formed on the second interlayer insulating layer 11. The third contact 13 connected to the lower electrode 20 may correspond to a storage node contact. The second dopant injection region 2b electrically connected to the third contact 13 may correspond to a source region.

A third interlayer insulating layer 30 may be formed to cover the capacitor 28, and a fourth contact 32 contacting the upper electrode 24 may be formed to penetrate the third interlayer insulating layer 30. A second etch stop layer 36, a plurality of second interconnections 34, and a fourth interlayer insulating layer 38 may be formed on the third interlayer insulating layer 30. The fourth interlayer insulating layer 38 covers the second etch stop layer 36 and the plurality of second interconnections 34. A third etch stop layer 40 and a fifth interlayer insulating layer 42 may be formed on the fourth interlayer insulating layer 38.

A fifth contact 44 may be formed to penetrate the fifth interlayer insulating layer 42 and the third etch stop layer 40. The fifth contact 44 may be electrically connected to the second interconnection 34. A third interconnection 48 electrically connected to the fifth contact 44 may be formed on the fifth interlayer insulating layer 42. The first to fifth interlayer insulating layers 7, 11, 30, 38, and 42 may be formed of a silicon oxide series material. The etch stop layers 15, 36, and 40 may be formed of a silicon nitride series material.

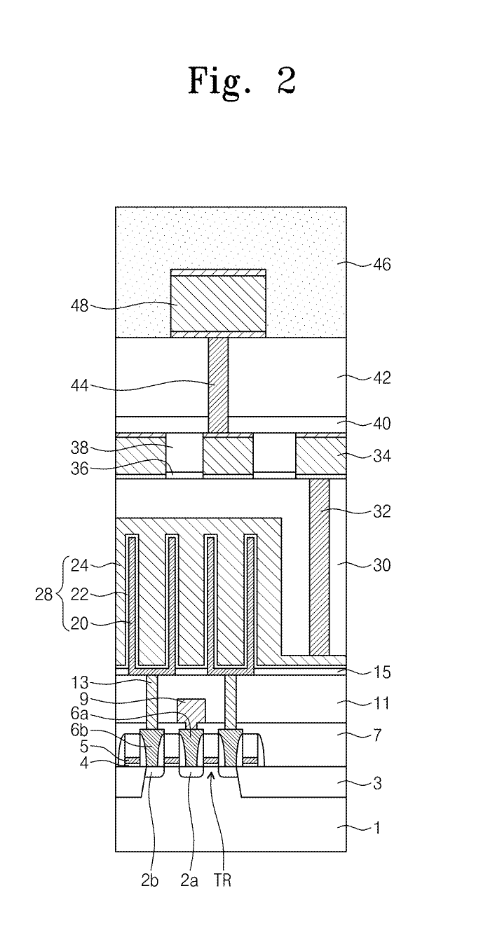

Referring to FIG. 2, a sixth interlayer insulating layer 46 covering the third interconnection 48 may be formed on the fifth interlayer insulating layer 42. The sixth interlayer insulating layer 46 may be formed to have hydrogen. For example, the sixth interlayer insulating layer 46 may be formed of a high density plasma (HDP) oxide layer containing hydrogen. The sixth interlayer insulating layer 46 including hydrogen is formed by a chemical vapor deposition (CVD) method using oxygen and silane. A flow rate of silane may have a range of about 50% to about 70% of a flow rate of oxygen. At this time, hydrogen remains the sixth interlayer insulating layer 46. The sixth interlayer insulating layer 46 may be formed to be porous. The sixth interlayer insulating layer 46 may include a relatively high hydrogen density. Thus, a density of the sixth interlayer layer 46 may become lower. For example, the sixth interlayer insulating layer 46 may have the density of about 2.21 g/cm³ or less. The sixth interlayer insulating layer 46 may have a tensile stress characteristic.

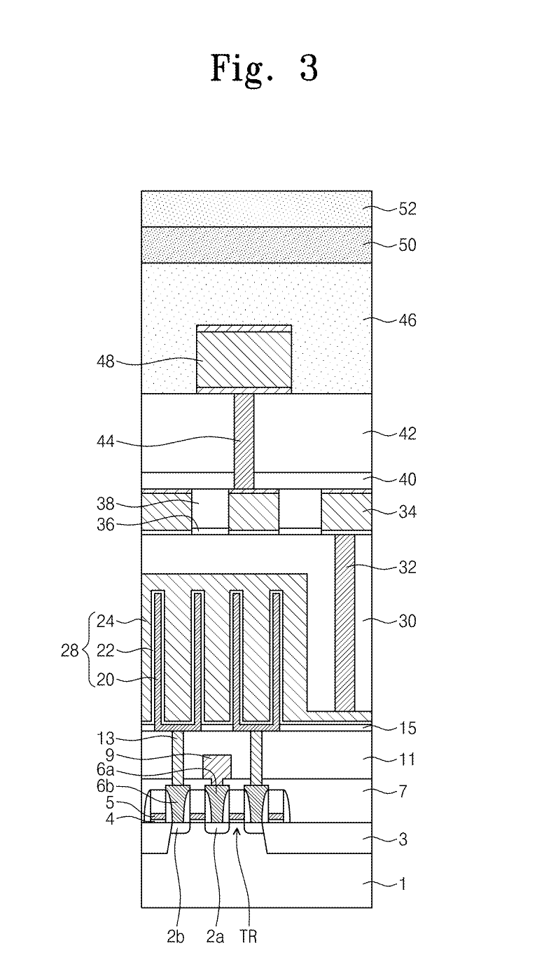

Referring to FIG. 3, a first passivation layer 50 may be formed on the sixth interlayer insulating layer 46. The first passivation layer 50 may be formed to have a relatively high density capable of preventing or inhibiting an out-gassing of hydrogen included in the sixth interlayer insulating layer 46. For example, the first passivation layer 50 may be formed of a silicon nitride layer having a density of about 2.6 g/cm³ or more. The first passivation layer 50 may be formed to have a thickness of about 2,000 Å or more. Because the first passivation layer 50 has the density of about 2.6 g/cm³ or more and/or the thickness of about 2000 Å or more, preventing or inhibiting the out-gassing of hydrogen may be possible. If the first passivation layer 50 has a density less than about 2.6 g/cm³, the out-gassing of hydrogen may not be prevented or inhibited. At this time, the first passivation layer 50 may have a relatively high compressive stress characteristic. For example, the stress value of the first passivation layer 50 may be 10¹⁰ dyne/cm².

Because the first passivation layer 50 has the relatively high compressive stress characteristic, a warpage of a wafer including the substrate 1 may occur. If the wafer is warped, a vacuum chuck error may occur in a photolithography process for a formation of subsequent pads. For preventing or inhibiting this, a second passivation layer 52 may be formed on the first passivation layer 50. The second passivation layer 52 has a density and/or a characteristic capable of controlling the warpage characteristic of the wafer. In other words, the second passivation layer 52 may have the stress characteristic and/or the density offsetting the stress characteristic of the first passivation layer 50 in order to satisfy a warpage degree target required in fabricating processes. For example, the second passivation layer 52 may be formed of a silicon nitride layer having a density lower than the density of the first passivation layer 50.

For example, the second passivation layer 52 may have a tensile stress characteristic reverse to the compressive stress characteristic. For example, the first and second passivation layers 50 and 52 may be formed using a CVD process. At this time, a density of a layer may be increased as a flow rate of source gas becomes reduced, as a power of a deposition chamber becomes increased, and/or as a deposition pressure becomes reduced. Thus, forming the first passivation layer 50 may be performed under a process condition having at least one of a gas flow rate lower than, a pressure lower than, and a power higher than forming the second passivation layer 52.

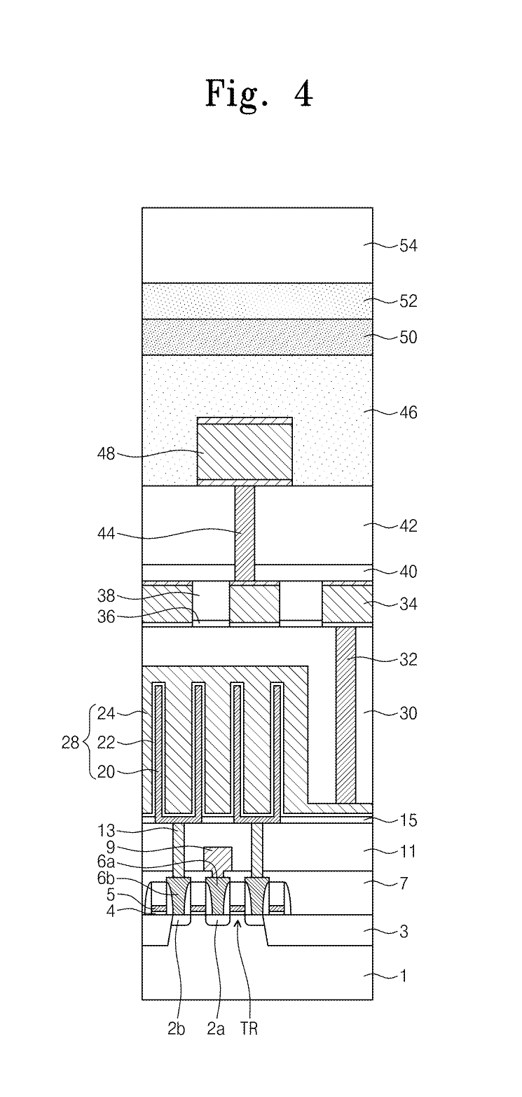

Referring to FIG. 4, a third passivation layer 54 may be formed on the second passivation layer 52. For example, the third passivation layer 54 may be formed of a polymer material, e.g., polyimide.

Even though not shown in the drawings, a photoresist pattern for opening a region in which the pad is formed may be formed on the third passivation layer 54. Because the warpage characteristic of the entire wafer is controlled by the second passivation layer 52 in a photolithography process for the formation of the photoresist, the vacuum chuck error may not occur.

Subsequently, a thermal treatment process may be performed to move the hydrogen in the sixth interlayer insulating layer 46 to the surface of the substrate 1 through the interconnections 48, 34, and 9 and the contacts 44, 32, and 6a. Thus, the moved hydrogen may be combined with a dangling bond of silicon of the substrate 1, thereby curing defects of the surface of the substrate 1. As a result, the dangling bond being a source of a leakage current is eliminated, so that the leakage current may be prevented or inhibited.

As described above, the semiconductor device of FIG. 4 corresponds to a dynamic random access memory (DRAM) device as an example embodiment of the inventive concepts. The semiconductor device of FIG. 4 includes the sixth interlayer insulating layer 46 containing hydrogen, the first passivation layer 50 having a first density preventing or inhibiting the out-gassing of hydrogen, and the second passivation layer 52 having a second density lower than the first density. Thus, preventing or inhibiting the leakage current may be possible. Particularly, in the DRAM device of example embodiments, a gate-induced drain leakage (GIDL) characteristic may be improved to improve a refresh characteristic.

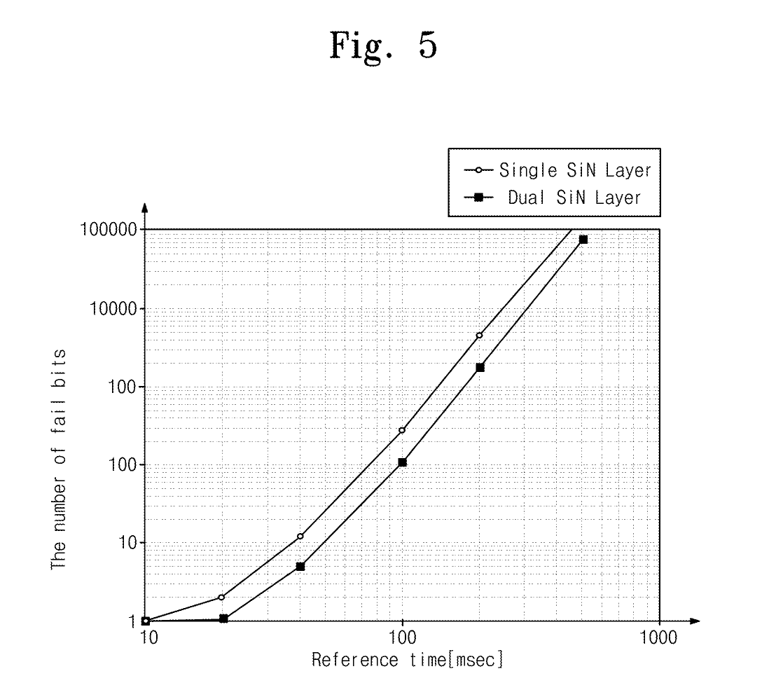

FIG. 5 is a graph showing the numbers of fail bits of samples 1 and 2 with respect to a reference time. The sample 1 is a DRAM device including a passivation of a single silicon nitride layer. The sample 2 is the DRAM device including a dual passivation layer of two silicon nitride layers corresponding to the first passivation layer 50 and the second passivation layer 52 according to example embodiments of the inventive concepts. Here, the number of fail bits represents the refresh characteristic. Particularly, the number of fail bits means the number of cells failing to preserve charges in the capacitor of the DRAM device by the GIDL phenomenon. Referring to FIG. 5, the numbers of fail bits of the sample 2 according to example embodiments of the inventive concepts are smaller than the numbers of fail bit of the sample 1 using the single silicon nitride layer throughout the reference time. Thus, the effect reducing the leakage current may be achieved in the semiconductor device and the methods of fabricating the same according to example embodiments of the inventive concepts.

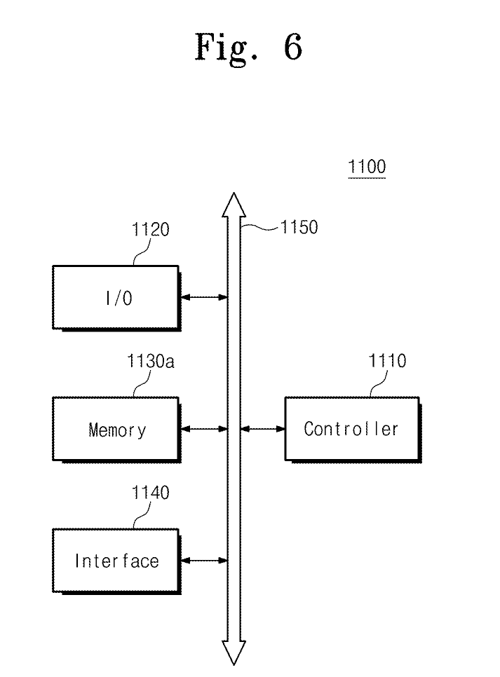

FIG. 6 is a schematic diagram illustrating an example of electronic systems including semiconductor devices according to example embodiments of the inventive concepts. Referring to FIG. 6, an electronic system 1100 according to example embodiments of the inventive concepts may include a controller 1110, an input/output (I/O) unit 1120, a memory device 1130a, an interface unit 1140 and a data bus 1150. At least two of the controller 1110, the I/O unit 1120, the memory device 1130a and the interface unit 1140 may communicate with each other through the data bus 1150. The data bus 1150 may correspond to a path through which electrical signals are transmitted.

The controller 1110 may include at least one of a microprocessor, a digital signal processor, a microcontroller or another logic device. The other logic device may have a similar function to any one of the microprocessor, the digital signal processor and the microcontroller. The I/O unit 1120 may include a keypad, a keyboard and/or a display unit. The memory device 1130a may store data and/or commands. The memory device 1130a may include the semiconductor device according to the example embodiments described above. The memory device 1130a may further include another type of semiconductor memory devices which are different from the semiconductor devices described above. For example, the memory device 1130a may further include a non-volatile memory device (e.g. a magnetic memory device, a phase change memory device, etc.), a dynamic random access memory (DRAM) device and/or a static random access memory (SRAM) device.

The interface unit 1140 may transmit electrical data to a communication network or may receive electrical data from a communication network. The interface unit 1140 may operate by wireless or cable. For example, the interface unit 1140 may include an antenna for wireless communication or a transceiver for cable communication. Although not shown in the drawings, the electronic system 1100 may further include a fast DRAM device and/or a fast SRAM device which acts as a cache memory for improving an operation of the controller 1110.

The electronic system 1100 may be applied to a personal digital assistant (PDA), a portable computer, a web tablet, a wireless phone, a mobile phone, a digital music player, a memory card or other electronic products. The other electronic products may receive or transmit information data by wireless.

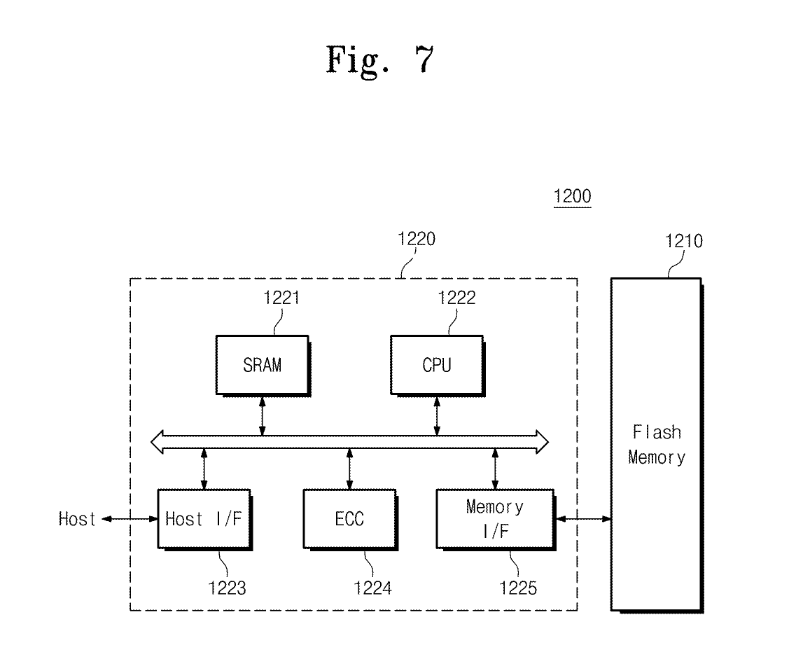

FIG. 7 is a schematic diagram illustrating an example of memory cards including semiconductor devices according to example embodiments of the inventive concepts. Referring to FIG. 7, a memory card 1200 according to example embodiments of the inventive concepts may include a memory device 1210. The memory device 1210 may include the semiconductor device according to the example embodiments mentioned above. In example embodiments, the memory device 1210 may further include another type of semiconductor memory devices which are different from the semiconductor devices according to the example embodiments described above. For example, the memory device 1210 may further include a non-volatile memory device (e.g. a magnetic memory device, a phase change memory device, etc.), a dynamic random access memory (DRAM) device and/or a static random access memory (SRAM) device. The memory card 1200 may include a memory controller 1220 that controls data communication between a host and the memory device 1210.

The memory controller 1220 may include a central processing unit (CPU) 1222 that controls overall operations of the memory card 1200. In addition, the memory controller 1220 may include an SRAM device 1221 used as an operation memory of the CPU 1222. Moreover, the memory controller 1220 may further include a host interface unit 1223 and a memory interface unit 1225. The host interface unit 1223 may be configured to include a data communication protocol between the memory card 1200 and the host. The memory interface unit 1225 may connect the memory controller 1220 to the memory device 1210. The memory controller 1220 may further include an error check and correction (ECC) block 1224. The ECC block 1224 may detect and correct errors of data which are read out from the memory device 1210. Even though not shown in the drawings, the memory card 1200 may further include a read only memory (ROM) device that stores code data to interface with the host. The memory card 1200 may be used as a portable data storage card. Alternatively, the memory card 1200 may realized as solid state disks (SSD) which are used as hard disks of computer systems.

According to example embodiments of the inventive concepts, hydrogen in the interlayer insulating layer may be moved to the surface of the substrate through the interconnection, so that the hydrogen may be combined with the dangling bond. Thus, reducing the leakage current may be possible. Particularly, the GIDL characteristic of the DRAM device may be improved.

Additionally, the first passivation layer may prevent or inhibit the out-gassing of the hydrogen. Thus, the hydrogen is not released to the external environment outside of the device but moves effectively to the surface of the substrate. As a result, effectively reducing the leakage current may be possible.

Furthermore, in the method of fabricating the semiconductor device according to example embodiments of the inventive concepts, the second passivation layer may be formed on the first passivation layer having the relatively high density for preventing or inhibiting the out-gassing of the hydrogen. The second passivation layer has the density lower than the first passivation layer, so that the second passivation layer has the tensile stress characteristic capable of offsetting the compressive stress characteristic of the first passivation layer. Thus, the method controls the warpage characteristic of the wafer.

While the inventive concepts have been described with reference to example embodiments, it will be apparent to those skilled in the art that various changes and modifications may be made without departing from the spirit and scope of the inventive concepts. Therefore, it should be understood that the above embodiments are not limiting, but illustrative. Thus, the scope of the inventive concepts is to be determined by the broadest permissible interpretation of the following claims and their equivalents, and shall not be restricted or limited by the foregoing description.

1. A semiconductor device comprising:
interconnections on a substrate;
an interlayer insulating layer covering the interconnections;
a first passivation layer on the interlayer insulating layer; and
a second passivation layer on the first passivation layer, the second passivation layer having a density lower than a density of the first passivation layer.

2. The semiconductor device of claim 1, wherein the first passivation layer is formed of a silicon nitride layer having the density of about 2.6 g/cm³ or more, and wherein the second passivation layer is formed of a silicon nitride layer having the density less than about 2.6 g/cm³.

3. The semiconductor device of claim 1, wherein the first passivation layer has a compressive stress characteristic, and
wherein the second passivation layer has a tensile stress characteristic.

4. The semiconductor device of claim 1, wherein the first passivation layer has a thickness of about 2,000 Å or more.

5. The semiconductor device of claim 1, wherein the semiconductor device is a DRAM device.

6. The semiconductor device of claim 1, further comprising:
a third passivation layer on the second passivation layer, the third passivation layer formed of polyimide.

7. The semiconductor device of claim 1, wherein the interlayer insulating layer has a tensile stress characteristic.

8. The semiconductor device of claim 1, wherein the interlayer insulating layer includes hydrogen, and the hydrogen is combined with a dangling bond of a surface of the substrate through the interconnections.

9. The semiconductor device of claim 1, wherein the interlayer insulating layer has a density of 2.21 g/cm³ or less.

10.-14. (canceled)

15. A semiconductor device comprising:
interconnections on a substrate;
at least one interlayer insulating layer on the interconnections; and
at least two passivation layers on the at least one interlayer insulating layer,
wherein one of the at least two passivation layers has a compressive stress characteristic, and the other of the at least two passivation layers has a tensile stress characteristic.

16. The semiconductor device of claim 15, wherein the at least two passivation layers include first and second passivation layers, and the first passivation layer has a thickness of about 2,000 Å or more.

17. The semiconductor device of claim 15, wherein the at least two passivation layers include first, second and third passivation layers, and the third passivation layer is formed of polyimide.

18. The semiconductor device of claim 17, wherein a density of each of the second and third passivation layers is less than a density of the first passivation layer.

19. The semiconductor device of claim 15, wherein the at least one interlayer insulating layer has a tensile stress characteristic.

20. The semiconductor device of claim 15, wherein the at least one interlayer insulating layer includes hydrogen, and the hydrogen is combined with a dangling bond of a surface of the substrate through the interconnections.
